(19) United States
(12) Patent Application Publication
(10) Pub. No.: US 2025/0191994 A1
(43) Pub. Date: Jun. 12, 2025

(54) SEMICONDUCTOR STRUCTURE AND METHOD OF FORMING THE SAME

(71) Applicant: MACRONIX INTERNATIONAL CO., LTD., HSINCHU (TW)

(72) Inventors: Yun-Yuan WANG, Kaohsiung City (TW); Cheng-Hsien LU, Taoyuan City (TW); Dai-Ying LEE, Hsinchu County (TW); Wei-Lun WENG, Tainan City (TW)

(21) Appl. No.: 18/534,862

(22) Filed: Dec. 11, 2023

(51) Int. Cl. H01L 23/367; H01L 21/311; H01L 21/56; H01L 23/373

(52) U.S. Cl. CPC H01L 23/3677; H01L 21/56; H01L 21/31111; H01L 23/3731; H01L 23/3736; H01L 23/3738

(57) ABSTRACT

A semiconductor structure includes a semiconductor substrate, and a heat dissipating component disposed on a surface of the semiconductor substrate. The heat dissipating component includes a plurality of protrusions. Each of the protrusions includes a plurality of first sections and a plurality of second sections, wherein a dimension of each of the first sections is different from a dimension of each of the second sections. A method of forming the semiconductor structure is also disclosed.

### BACKGROUND

### Field of Invention

The present disclosure relates to a semiconductor structure and method of forming the same.

### Description of Related Art

High efficiency, high power, high density and high reliability are trends of developments of the electronic devices. However, the heat generated by the electronic devices is increased accordingly. Therefore, there is a need to improve heat dissipating efficiency of the electronic devices.

### SUMMARY

An aspect of the disclosure provides a semiconductor structure. The semiconductor structure includes a semiconductor substrate, and a heat dissipating component disposed on a surface of the semiconductor substrate. The heat dissipating component includes a plurality of protrusions. Each of the protrusions includes a plurality of first sections and a plurality of second sections, wherein a dimension of the first sections is different from a dimension of the second sections.

In some embodiments, the semiconductor structure further includes a liner oxide layer on the surface of the semiconductor substrate, and a seed layer on the liner oxide layer. The bottoms of the protrusions are interconnected by the seed layer.

In some embodiments, a material of the protrusions of the heat dissipating component includes Ag, Cu, Au, Al, or W.

In some embodiments, the protrusions are directly formed on the surface of the semiconductor substrate, and bottoms of the protrusions are spaced apart from each other.

In some embodiments, bottoms of the protrusions are embedded in the surface of the semiconductor substrate.

In some embodiments, a material of the protrusions of the heat dissipating component includes graphite sheet, Si, phase change material, liquid metal paste, thermal pad, thermal paste, or AlN.

In some embodiments, the first sections and the second sections are alternately and repetitively arranged.

In some embodiments, each of the protrusions includes a plurality of third sections, wherein a dimension of the third sections is different from the dimension of the first sections and is different from the dimension of the second sections.

In some embodiments, the semiconductor structure further includes a via disposed in the semiconductor substrate, wherein the via is connected to one or more of the protrusions.

Another aspect of the disclosure provides a semiconductor structure. The semiconductor structure includes a first semiconductor substrate having a front side and a back side, a second semiconductor substrate having a front side and a back side, and a heat dissipating component. The front side of the second semiconductor substrate is bonded to the front side of the first semiconductor substrate. The heat dissipating component is disposed on the back side of the first semiconductor substrate. The heat dissipating component includes a plurality of protrusions. Each of the protrusions includes a plurality of first sections and a plurality of second sections. A dimension of the first sections is different from a dimension of the second sections.

In some embodiments, the semiconductor structure further includes a plurality of bonding pads disposed on the back side of the second semiconductor substrate.

In some embodiments, the first semiconductor substrate is a CMOS wafer, and the second semiconductor substrate is an array wafer.

In some embodiments, the first semiconductor substrate is an array wafer, and the second semiconductor substrate is a CMOS wafer.

Another aspect of the disclosure provides a method of forming a semiconductor structure. The method includes forming a sacrificial stack on a surface of a semiconductor substrate, wherein the sacrificial stack includes a plurality of first sacrificial layers and a plurality of second sacrificial layers alternately and repetitively arranged, and a material of the first sacrificial layers is different from a material of the second sacrificial layers. An anisotropic etching process is performed to the sacrificial stack to form a plurality of trenches between a plurality of sacrificial structures includes the first sacrificial layers and the second sacrificial layers. An isotropic etching process is performed to the sacrificial structures to form a plurality of cavities between the first sacrificial layers and the second sacrificial layers. A thermal conductivity material is filled in the trenches and the cavities, and the sacrificial structures are removed. A remaining portion of the thermal conductivity material forms a plurality of protrusions of a heat dissipating component on the surface of a semiconductor substrate.

In some embodiments, the method further includes removing a portion of the thermal conductivity material to expose top surfaces of the sacrificial structures, before removing the sacrificial structures.

In some embodiments, the sacrificial stack includes a plurality of third sacrificial layers, and a material of the third sacrificial layers is different from the material of the first sacrificial layers and is different from the material of the second sacrificial layers.

In some embodiments, a thickness of the third sacrificial layers is different from a thickness of the first sacrificial layers and is different from a thickness of the second sacrificial layers.

In some embodiments, the method further includes thinning the semiconductor substrate, prior to forming the sacrificial stack on the surface of the semiconductor substrate.

In some embodiments, the method further includes forming a liner oxide layer on the surface of the semiconductor substrate, and forming a seed layer on the liner oxide layer. The sacrificial stack is formed on the seed layer.

In some embodiments, filling a thermal conductivity material in the trenches and the cavities includes performing an electroplating process.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is an oblique view of a semiconductor structure, according to some embodiments of the disclosure.

FIG. 2 is a top view of the semiconductor structure of FIG. 1.

FIG. 3 is a cross-sectional view of the semiconductor structure of FIG. 1.

FIG. 4 to FIG. 10 are cross-sectional views of different steps of a method of forming a semiconductor structure, according to some embodiments of the disclosure.

FIG. 11 to FIG. 15 are cross-sectional views of different steps of a method of forming a semiconductor structure, according to some embodiments of the disclosure.

FIG. 16 to FIG. 18 are cross-sectional views of different steps of a method of forming a semiconductor structure, according to some embodiments of the disclosure.

FIG. 19A to FIG. 19E are schematic top views of the protrusions of the heat dissipating component of the semiconductor structure, according to various embodiments of the disclosure.

FIG. 20A and FIG. 20B are schematic top views of the protrusions of the heat dissipating component of the semiconductor structure, according to various embodiments of the disclosure.

FIG. 21 is a cross-sectional view of a semiconductor structure, according to some embodiments of the disclosure.

FIG. 22 and FIG. 23 are cross-sectional views of a semiconductor structure, according to different embodiments of the disclosure.

FIG. 24 is a schematic top view of a semiconductor structure, according to some embodiments of the disclosure.

FIG. 25 is a schematic top view of a semiconductor structure, according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

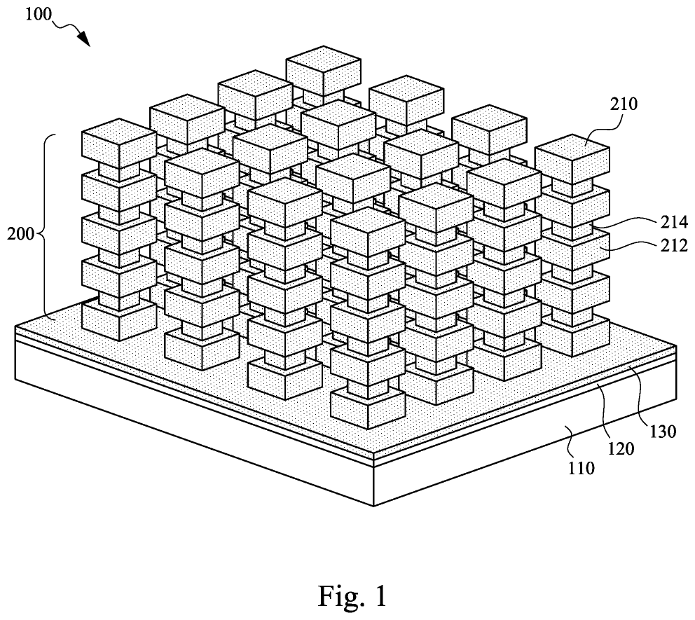

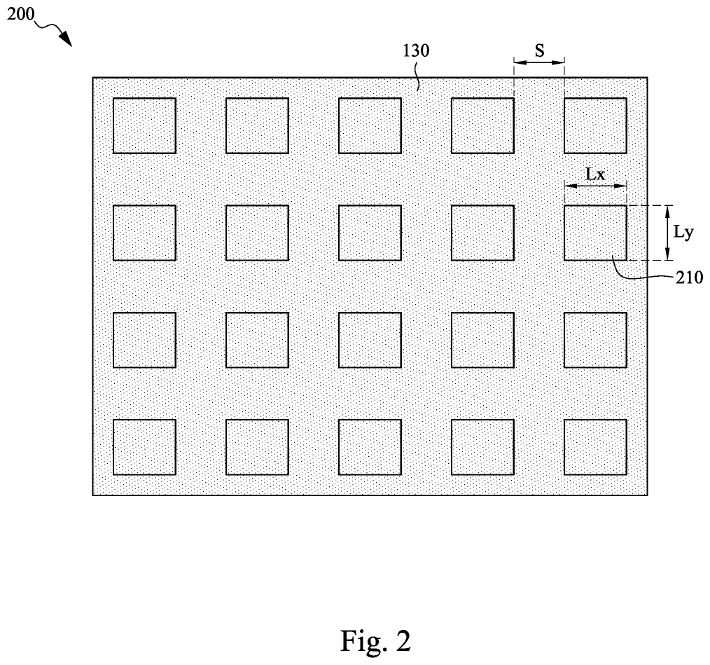

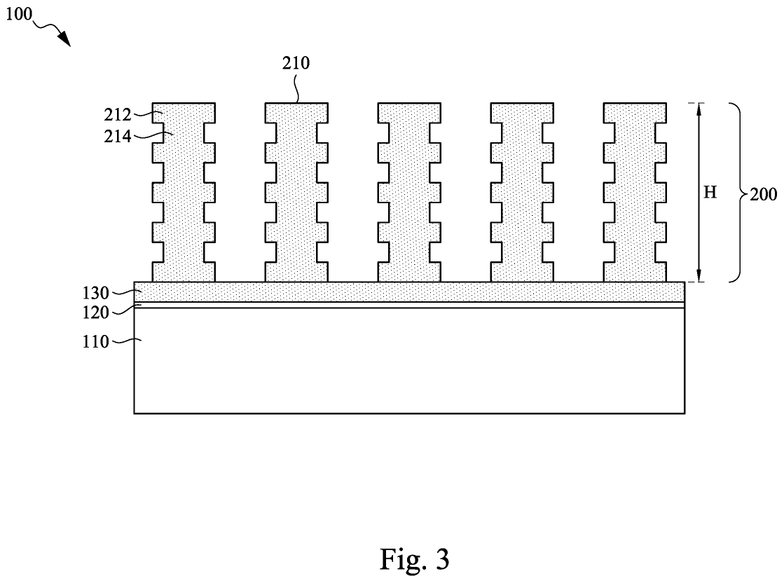

Reference is made to FIG. 1 to FIG. 3. FIG. 1 is an oblique view of a semiconductor structure, according to some embodiments of the disclosure. FIG. 2 is a top view of the semiconductor structure of FIG. 1. FIG. 3 is a cross-sectional view of the semiconductor structure of FIG. 1. The present disclosure provides a semiconductor structure 100 having a heat dissipating component 200. The semiconductor structure 100 includes a semiconductor substrate 110, a liner oxide layer 120 on a surface of the semiconductor substrate 110, and the heat dissipating component 200 on the liner oxide layer 120. The heat dissipating component 200 is made of thermal conductivity material and is integrately formed. More particularly, the heat dissipating component 200 has a plurality of protrusions 210 standing a seed layer 130 on the liner oxide layer 120, in which the liner oxide layer 120 is on the semiconductor substrate 110. Each of the protrusions 210 has a wrinkle side surface thereby increasing the surface area of the protrusions 210 to improve the thermal exchange efficiency of the heat dissipating component 200.

In some embodiments, the semiconductor substrate 110 may be or include a bulk semiconductor substrate (e.g., a bulk silicon substrate), a silicon-on-insulator (SOI) substrate, or another suitable substrate material. In some embodiments, the semiconductor substrate 110 may include one or more doped region. In some embodiments, the semiconductor substrate 110 may include integrated circuit layers and/or semiconductor components. In some other embodiments, the semiconductor substrate 110 may be a wafer or a chip.

In some embodiments, the heat dissipating component 200 is fabricated by a series of semiconductor processes including deposition processes, lithography processes, and etching processes. In some embodiments, each of the protrusions 210 of the heat dissipating component 200 has a plurality of first sections 212 and a plurality of second sections 214, in which a dimension of each of the first sections 212 is larger than a dimension of each of second sections 214. For example, the first sections 212 and the second sections 214 are rectangular, and a width or a length (Lx or Ly) of the first section 212 is larger than a width or a length of the second section 214.

In some embodiments, in order to provide sufficient thermal exchange area without adding extra space of the heat dissipating component 200, the height H of each of the protrusions 210 is in a range from 100 μm to 5000 μm, the space S between adjacent two of the protrusions 210 is in a range from 50 μm to 500 μm, and a width Lx or a length Ly of each of the protrusions 210 is in a range from 50 μm to 50 mm.

The space S between the protrusions 210 can be regarded as a flow channel to allow a medium passing through to thermal exchange with the wrinkle side surface of the protrusions 210 of the heat dissipating component 200. In some embodiments, the heat dissipating component 200 is an air cooling type heat dissipating component, and the medium passing through the space S is air. In some embodiments, the heat dissipating component 200 is a water cooling type heat dissipating component, and the medium passing through the space S is a fluid.

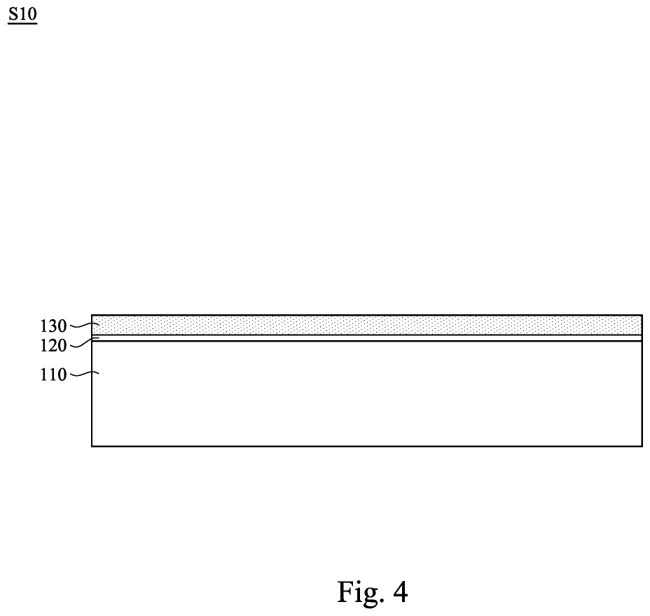

Reference is made to FIG. 4 to FIG. 10, which are cross-sectional views of different steps of a method of forming a semiconductor structure, according to some embodiments of the disclosure. As shown in FIG. 4, the method of forming a semiconductor structure begins at step S10, a semiconductor substrate 110 is provided. The semiconductor substrate 110 may be or include a bulk semiconductor substrate (e.g., a bulk silicon substrate), a silicon-on-insulator substrate, or another suitable substrate material. In some embodiments, the semiconductor substrate 110 may include one or more doped region. In some embodiments, the semiconductor substrate 110 may include integrated circuit layers and/or semiconductor components. In some other embodiments, the semiconductor substrate 110 may be a wafer or a chip. In some embodiments, a thinning process is performed to the semiconductor substrate 110 to reduce the thickness of the semiconductor substrate 110.

In step S10, a liner oxide layer 120 is deposited on the surface of the semiconductor substrate 110, and a seed layer 130 is further deposited on the liner oxide layer 120. In some embodiments, the material of the liner oxide layer 120 is SiO₂, and the material of the seed layer 130 is metal such as Cu. The liner oxide layer 120 serves as a lining layer to prevent Cu from the seed layer 130 diffusing into the semiconductor substrate 110. In some embodiments, the seed layer 130 can be a single layer or a multilayer structure, and the seed layer 130 provides good adhesion ability to the semiconductor substrate 110.

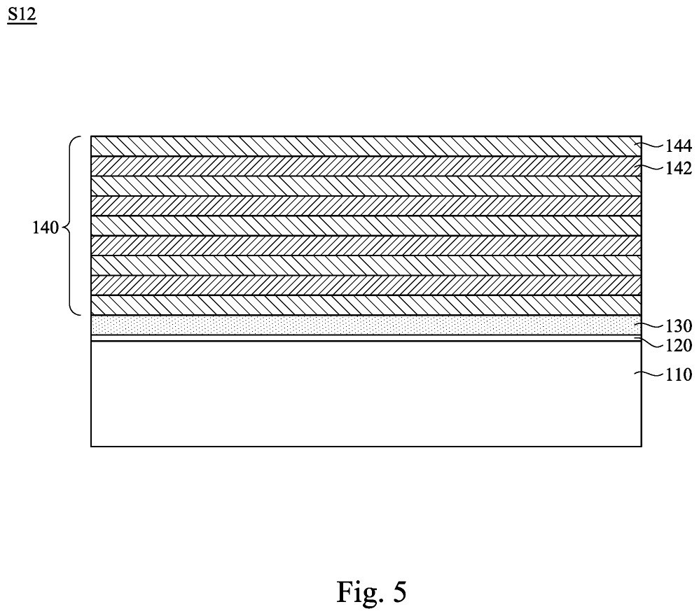

Reference is made to FIG. 5. In step S12, a sacrificial stack 140 is formed on the seed layer 130. The sacrificial stack 140 includes a plurality of first sacrificial layers 142 and a plurality of second sacrificial layers 144 alternately and repetitively arranged. In some embodiments, the first sacrificial layers 142 and the second sacrificial layers 144 are formed a cycles of deposition processes, and the thickness of each of the first sacrificial layers 142 and the second sacrificial layers 144 is in a range from tens of nanometers to tens of micrometers. In some embodiments, the thickness of each of the first sacrificial layers 142 and the thickness of each of the second sacrificial layers 144 can be the same or different.

The first sacrificial layers 142 and the second sacrificial layers 144 are made of dielectric materials, and the material of the first sacrificial layers 142 is different from the material of the second sacrificial layers 144, to provide sufficient etching selectivity between the first sacrificial layers 142 and the second sacrificial layers 144. For example, the material of the first sacrificial layers 142 is an oxide such as SiO₂, and the material of the second sacrificial layers 144 is a nitride such as SiN.

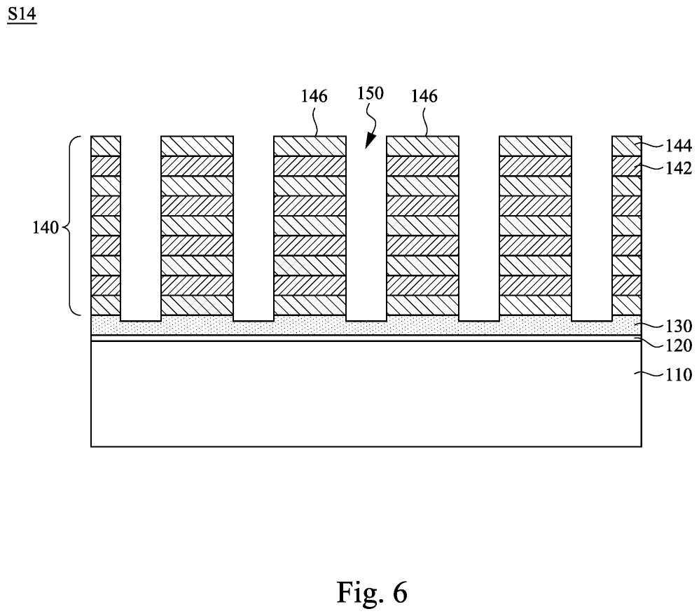

Reference is made to FIG. 6. In step S14, an anisotropic etching process is performed to pattern the sacrificial stack 140. The anisotropic etching process is directional and the etching rate to the first sacrificial layers 142 and the second sacrificial layers 144 are substantially the same. The anisotropic etching process stops at the seed layer 130. In some embodiments, the anisotropic etching process removes portions of the sacrificial stack 140, and the removing portions of the sacrificial stack 140 can be grid or linear thereby forming grid or linear trenches 150 in the sacrificial stack 140. A plurality of sacrificial structures 146 are formed on the seed layer 130 after the anisotropic etching process is performed. The trenches 150 are formed between the sacrificial structures 146. The side surfaces of the first sacrificial layers 142 and the second sacrificial layers 144 of the sacrificial structures 146 are exposed by the trenches 150.

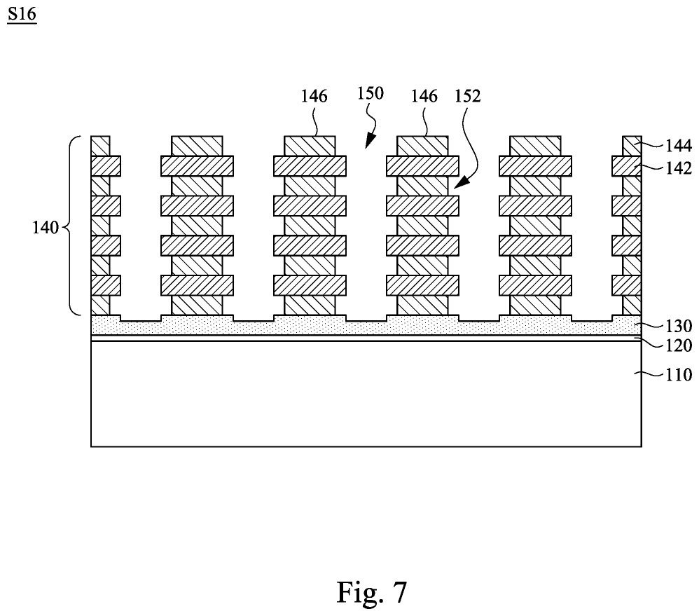

Reference is made to FIG. 7. In step S16, an isotropic etching process is performed. The etchant utilized in the isotropic etching process has an etching selectivity between the first sacrificial layers 142 and the second sacrificial layers 144. For example, in some embodiments, the etchant utilized in the isotropic etching process can be heated H₃PO₄ which etches SiN much faster than etches SiO₂, such that the second sacrificial layers 144 are recessed from the first sacrificial layers 142 after the isotropic etching process is performed thereby forming cavities 152 between the first sacrificial layers 142 and the second sacrificial layers 144.

In some other embodiments, the etchant utilized in the isotropic etching process can be buffered oxide etchant (BOE) which etches SiO₂ much faster than etches SiN, such that the first sacrificial layers 142 are recessed from the second sacrificial layers 144 after the isotropic etching process is performed.

Preferably, the topmost layer of the sacrificial structures 146 is recessed from the underlying layer. For example, if the topmost layer is the first sacrificial layer 142 (e.g. SiO₂ layer), the etchant utilized in the isotropic etching process can be BOE. If the topmost layer is the second sacrificial layer 144 (e.g. SiN layer), the etchant utilized in the isotropic etching process can be heated H₃PO₄.

The side surfaces of the first sacrificial layers 142 and the second sacrificial layers 144 after the isotropic etching process is performed can be flat surfaces, concave surfaces, or convex surfaces, depending on the situations of the isotropic etching process.

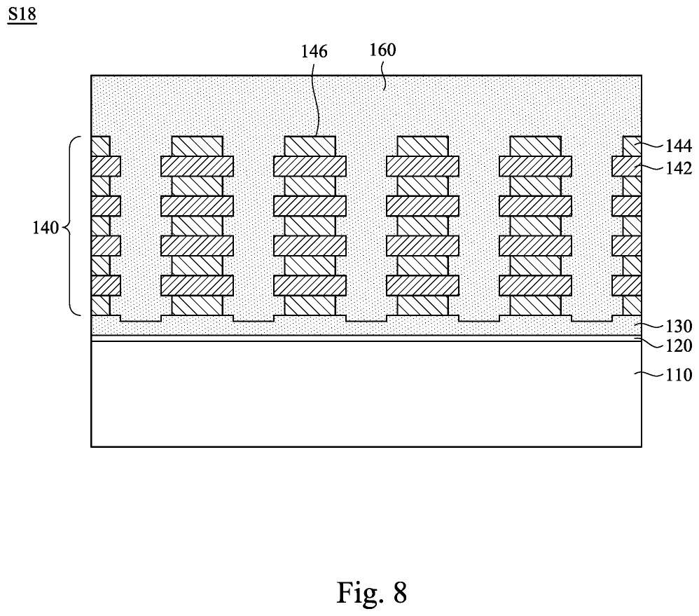

Reference is made to FIG. 8. In step S18, a thermal conductivity material 160 is provided to fill the trenches 150 (as shown in FIG. 7) between the sacrificial structures 146 and to fill the cavities 152 (as shown in FIG. 7) between the first sacrificial layers 142 and the second sacrificial layers 144. The thermal conductivity material 160 covers the top surfaces of the sacrificial structures 146.

In some embodiments, the material of the thermal conductivity material 160 is metal. For example, the material of the thermal conductivity material 160 can include Ag, Cu, Au, Al, or W. The thermal conductivity material 160 can be formed on the seed layer 130 by performing an electroplating process.

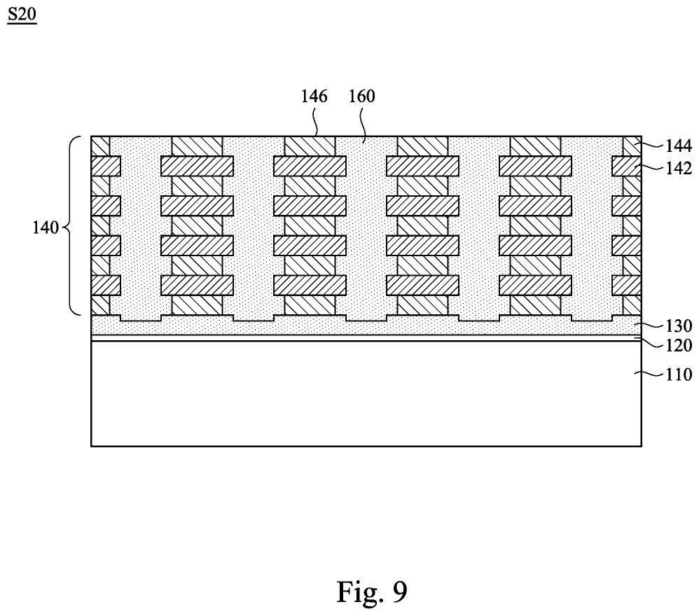

Reference is made to FIG. 9. In step S20, a planarization process such as a chemical mechanical polishing process is performed to remove a portion of the thermal conductivity material 160. The top surfaces of the sacrificial structures 146 are exposed from the thermal conductivity material 160 after the planarization process is performed.

Reference is made to FIG. 10. In step S22, a removal process is performed to remove the sacrificial structures 146 (as shown in FIG. 9), and the remaining portions of the thermal conductivity material 160 (as shown in FIG. 9) become the protrusions 210 of the heat dissipating component 200. The bottom of the protrusions 210 of the heat dissipating component 200 are interconnected by the seed layer 130. The removal process includes using a first isotropic etching process to remove the first sacrificial layers 142 and using a second isotropic etching process to remove the second sacrificial layers 144.

Each of the protrusions 210 includes the first sections 212 and the second sections 214 that are alternately arranged, in which the dimension of the first sections 212 is different from the dimension of the second sections 214. More particularly, the first sections 212 and the second sections 214 are defined by the profile of second sacrificial layers 144 and the first sacrificial layers 142 (as shown in FIG. 7) after the isotropic etching process.

In some other embodiments, the heat dissipating component 200 can be made of thermal conductivity material other than metal, and thus the liner oxide layer and the seed layer can be omitted.

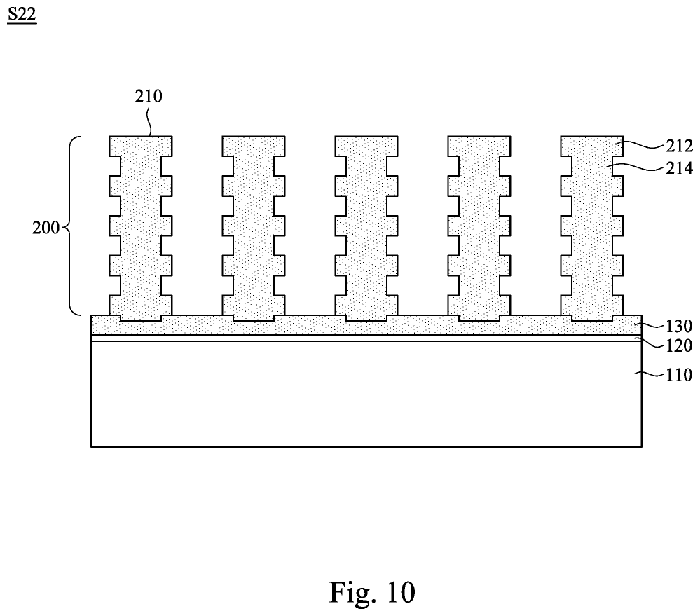

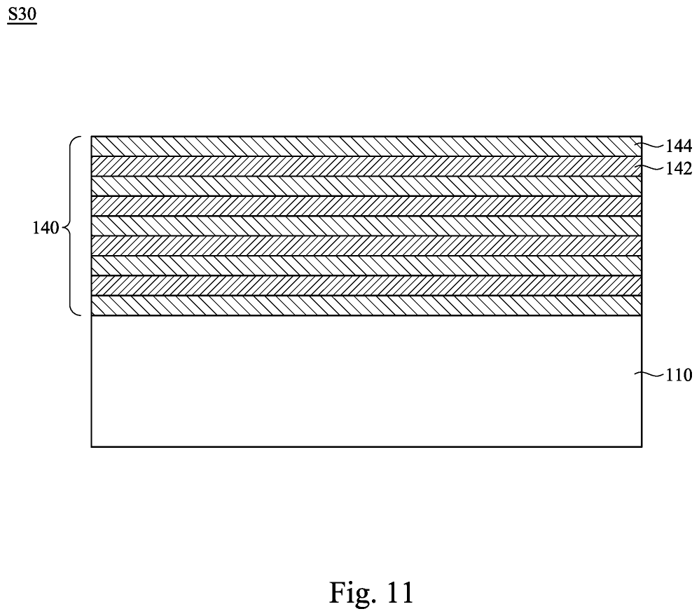

Reference is made to FIG. 11 to FIG. 15, which are cross-sectional views of different steps of a method of forming a semiconductor structure, according to some embodiments of the disclosure. As shown FIG. 11, the method of forming the semiconductor structure begins at step S30, in which the sacrificial stack 140 is directly formed on the semiconductor substrate 110. The sacrificial stack 140 includes the first sacrificial layers 142 and the second sacrificial layers 144 alternately and repetitively arranged. The material of the first sacrificial layers 142 is different from the material of the second sacrificial layers 144, to provide etching selectivity between the first sacrificial layers 142 and the second sacrificial layers 144. For example, the material of the first sacrificial layers 142 is an oxide such as SiO₂, and the material of the second sacrificial layers 144 is a nitride such as SiN.

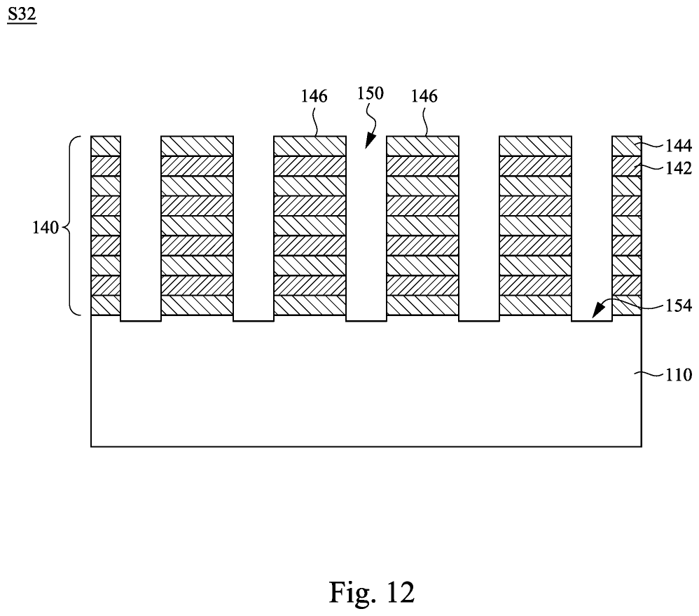

Reference is made to FIG. 12. In step S32, an anisotropic etching process is performed to pattern the sacrificial stack 140 to form the trenches 150 between the sacrificial structures 146 after the anisotropic etching process is performed. In some embodiments, the anisotropic etching process stops at the semiconductor substrate 110, and a plurality of concave portions 154 are formed on the top surface of the semiconductor substrate 110 after the anisotropic etching process is performed.

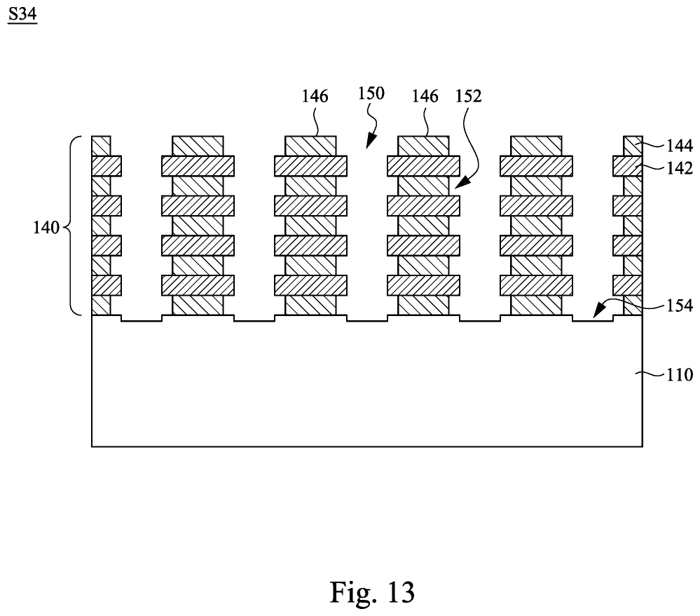

Reference is made to FIG. 13. In step S34, an isotropic etching process is performed. The etchant utilized in the isotropic etching process has an etching selectivity between the first sacrificial layers 142 and the second sacrificial layers 144. For example, in some embodiments, the etchant utilized in the isotropic etching process can be heated H₃PO₄ which etches SiN much faster than etches SiO₂, such that the second sacrificial layers 144 are recessed from the first sacrificial layers 142 after the isotropic etching process is performed thereby forming cavities 152 between the first sacrificial layers 142 and the second sacrificial layers 144.

In some other embodiments, the etchant utilized in the isotropic etching process can be buffered oxide etchant (BOE) which etches SiO₂ much faster than etches SiN, such that the first sacrificial layers 142 are recessed from the second sacrificial layers 144 after the isotropic etching process is performed.

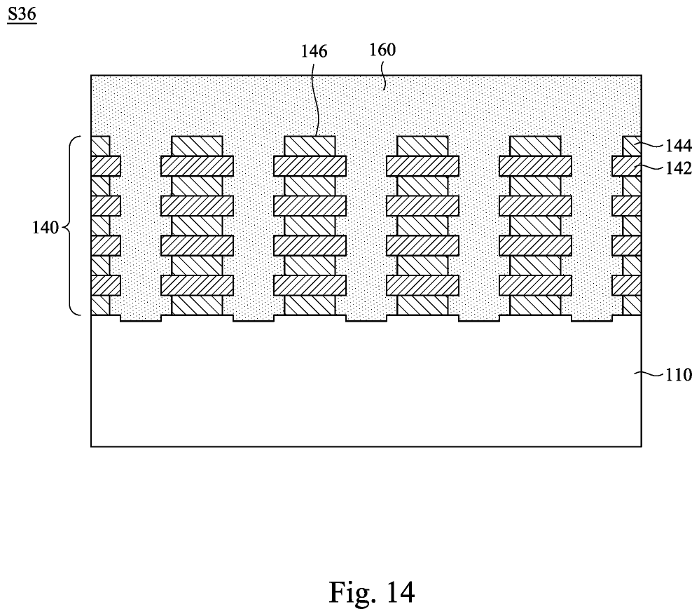

Reference is made to FIG. 14. In step S36, a thermal conductivity material 160 is provided to fill the trenches 150 (as shown in FIG. 13) between the sacrificial structures 146 and fill the cavities 152 (as shown in FIG. 13) between the first sacrificial layers 142 and the second sacrificial layers 144. The thermal conductivity material 160 further fills the concave portions 154 (as shown in FIG. 13) on the top surface of the semiconductor substrate 110.

In some embodiments, the material of the thermal conductivity material 160 is silicon. In some embodiments, the material of the thermal conductivity material 160 is graphite sheet. In some embodiments, the material of the thermal conductivity material 160 is phase change material. In some embodiments, the material of the thermal conductivity material 160 is metal paste. In some embodiments, the material of the thermal conductivity material 160 is thermal pad or thermal paste. In some embodiments, the material of the thermal conductivity material 160 is AlN. The thermal conductivity material 160 can be formed by deposition, filling, or any suitable process.

Reference is made to FIG. 15. In step S38, a planarization process is performed to remove a portion of the thermal conductivity material 160 to expose the top surfaces of the sacrificial structures 146 (as shown in FIG. 14), and a removal process is performed to remove the sacrificial structures 146. The heat dissipating component 200 having the protrusions 210 are directly formed on the semiconductor substrate 110. Each of the protrusions 210 includes the first sections 212 and the second sections 214 that are alternately arranged, in which the dimension of the first sections 212 is different from the dimension of the second sections 214. The bottoms of the protrusions 210 are spaced apart from each other, and the bottoms of the protrusions 210 are embedded in the semiconductor substrate 110. The embedded bottoms of the protrusions 210 can provide more contact area between the protrusions 210 and the semiconductor substrate 110 thereby providing more thermal exchanging area there between.

In yet some other embodiments, the side surface of the protrusions 210 of the heat dissipating component 200 can be more irregular, by modifying the composition of the sacrificial stack 140.

Reference is made to FIG. 16 to FIG. 18, which are cross-sectional views of different steps of a method of forming a semiconductor structure, according to some embodiments of the disclosure. The method of forming the semiconductor structure begins at step S40, in which a sacrificial stack 140 is directly formed on the semiconductor substrate 110 or on the seed layer 130, if exists. The sacrificial stack 140 includes a plurality of first sacrificial layers 142, second sacrificial layers 144, and third sacrificial layers 148, although only one second sacrificial layer 144 and third sacrificial layer 148 are illustrated. The first sacrificial layers 142, second sacrificial layers 144, and third sacrificial layers 148 are made of different materials, respectively. For example, the materials of the first sacrificial layers 142, second sacrificial layers 144, and third sacrificial layers 148 can be SiO₂, SiN, SiON, SiCN, or other suitable materials that can provide sufficient etching selectivity.

In some embodiments, the number and the sequence of the first sacrificial layers 142, second sacrificial layers 144, and third sacrificial layers 148 can be varied, and the thicknesses of each of the first sacrificial layers 142, second sacrificial layers 144, and third sacrificial layers 148 can be different as well. As a result, the variations of the sacrificial stack 140 can be increased.

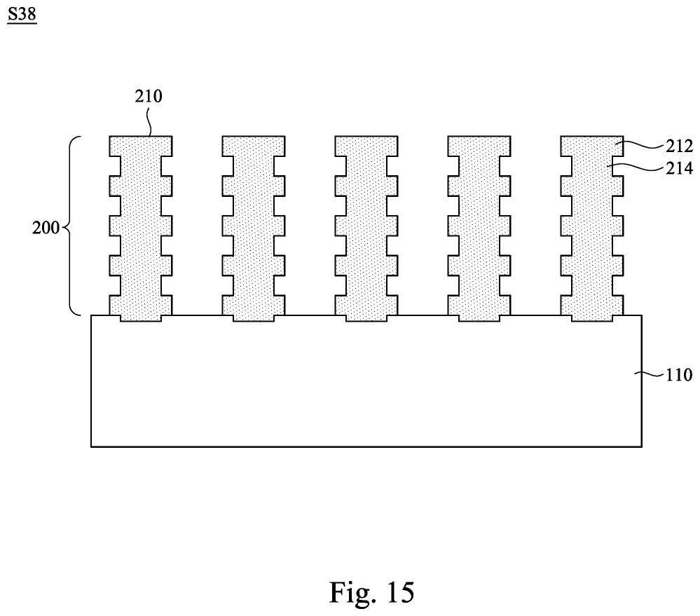

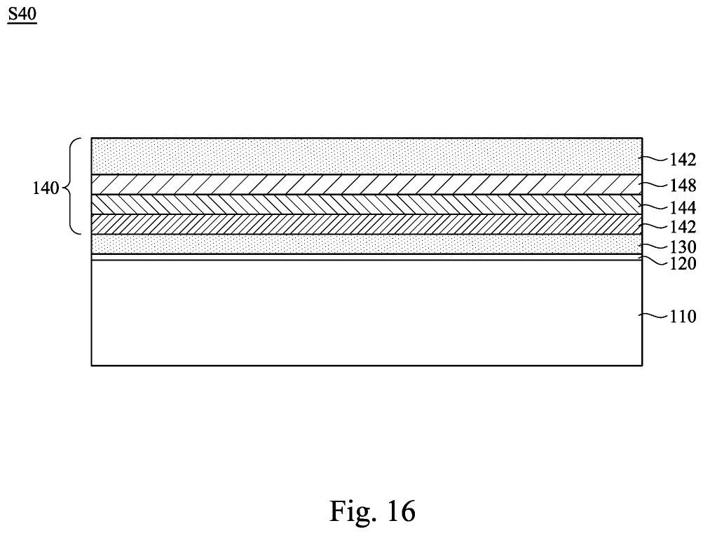

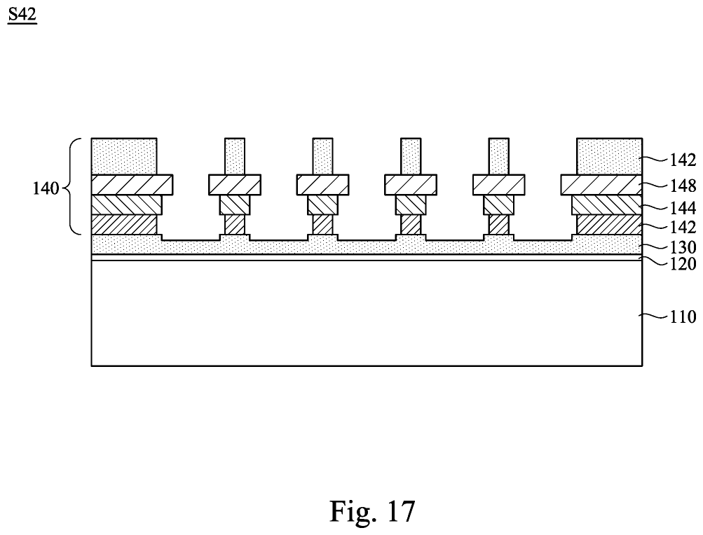

Reference is made to FIG. 17. In step S42, the sacrificial stack 140 is patterned by sequence of anisotropic etching process and isotropic etching processes. Due to etching selectivity of the materials of the first sacrificial layers 142, second sacrificial layers 144, and third sacrificial layers 148, the shape of the sacrificial structures 146 is more irregular. The spaces between the first sacrificial layers 142, second sacrificial layers 144, and third sacrificial layers 148 of the sacrificial structures 146 are more uneven.

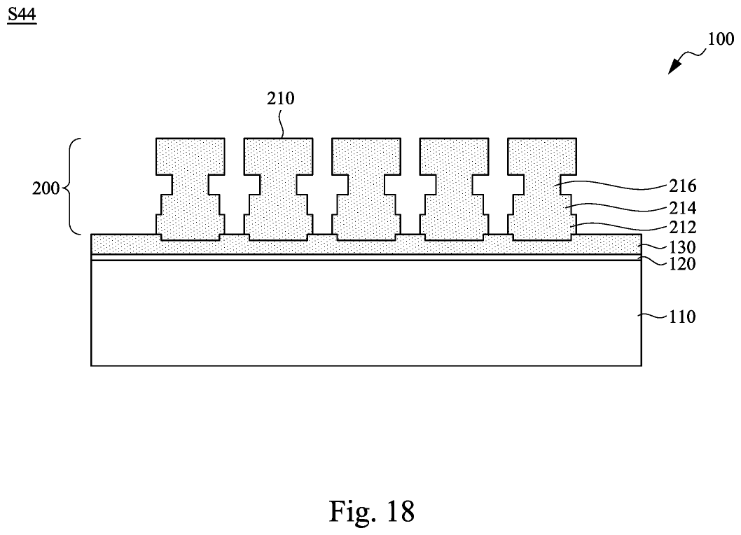

Reference is made to FIG. 18. In step S44, a plurality of protrusions 210 defined by the sacrificial structures 146 are formed on the semiconductor substrate 110 or on the seed layer 130, if exists. The protrusions 210 includes a plurality of first sections 212, second sections 214, and third sections 216, although only one second section 214 and third section 216 are illustrated. The dimensions and/or the thickness of the first sections 212, second sections 214, and third sections 216 can be different. Each of the protrusions 210 of the heat dissipating component 200 has an increased side surface thereby improving thermal exchanging area of the heat dissipating component 200.

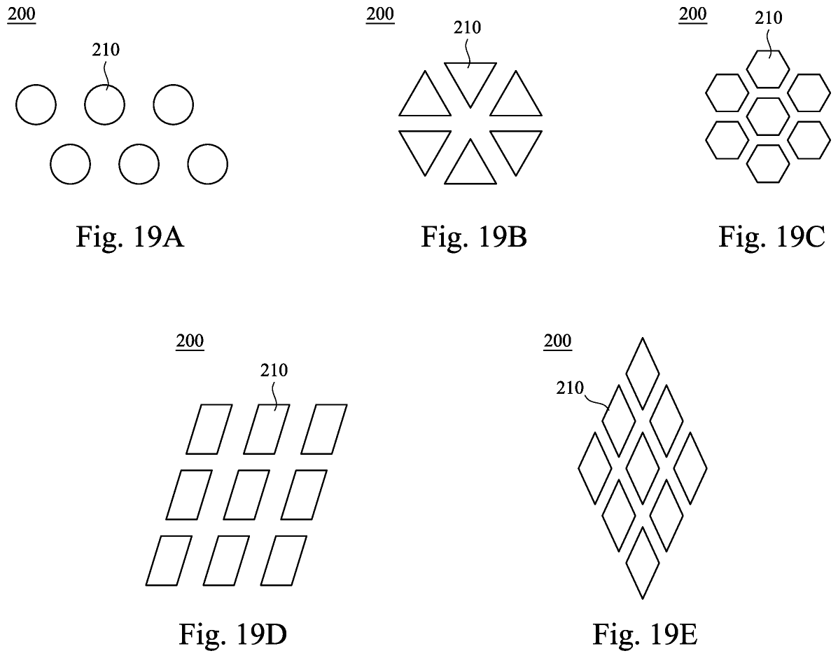

Reference is made to FIG. 19A to FIG. 19E, which are schematic top views of the protrusions of the heat dissipating component of the semiconductor structure, according to various embodiments of the disclosure. In some embodiments, the top cross-sectional view of the protrusions 210 of the heat dissipating component 200 is not restricted to be square or rectangular. In some embodiments, the top cross-sectional view of the protrusions 210 of the heat dissipating component 200 is not align or symmetric in X or Y direction. For example, the top cross-sectional view of the protrusions 210 of the heat dissipating component 200 can be circular (as shown in FIG. 19A), triangle (as shown in FIG. 19B), polygonal (as shown in FIG. 19C), parallelogram (as shown in FIG. 19D) or rhombus (as shown in FIG. 19E).

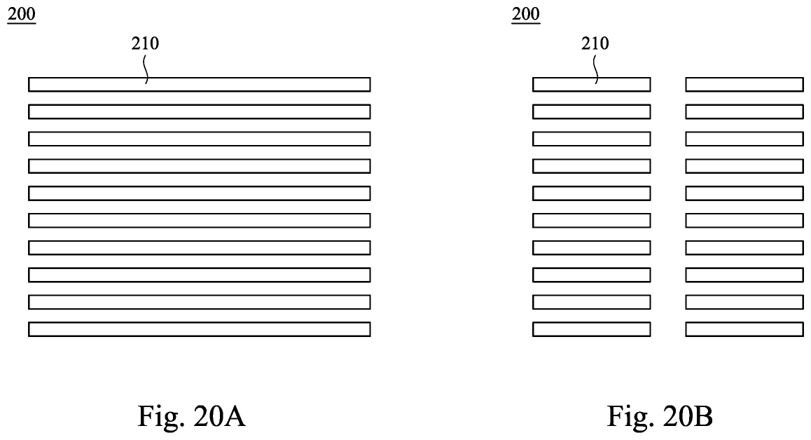

Reference is made to FIG. 20A and FIG. 20B, which are schematic top views of the protrusions of the heat dissipating component of the semiconductor structure, according to various embodiments of the disclosure. In some embodiments, the shape of the protrusions 210 of the heat dissipating component 200 can be strip (as shown in FIG. 20A) or fin (as shown in FIG. 20B).

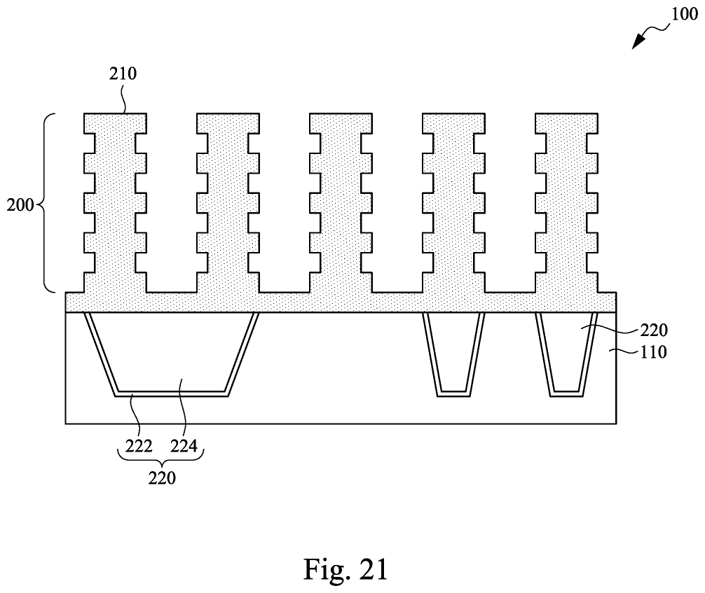

Reference is made to FIG. 21. FIG. 21 is a cross-sectional view of a semiconductor structure, according to some embodiments of the disclosure. In some embodiments, the semiconductor structure 100 further includes a plurality of vias 220 disposed in the semiconductor substrate 110 and connected to the heat dissipating component 200. Each of the vias 220 can be connected to one or more protrusions 210 of the heat dissipating component 200. Each of the vias 220 can include a metal core 224 and an adhesion layer 222 between the metal core 224 and the semiconductor substrate 110. The vias 220 are dummy vias which do not provide electrical function. The vias 220 in the semiconductor substrate 110 provides additional thermal exchange path thereby enhancing the heat dissipating efficiency of the semiconductor structure 100.

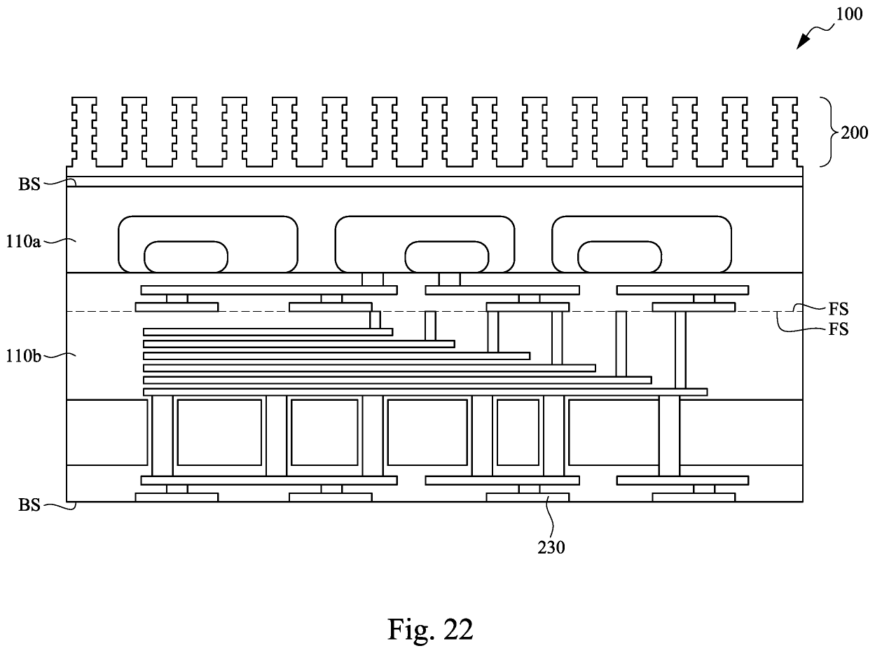

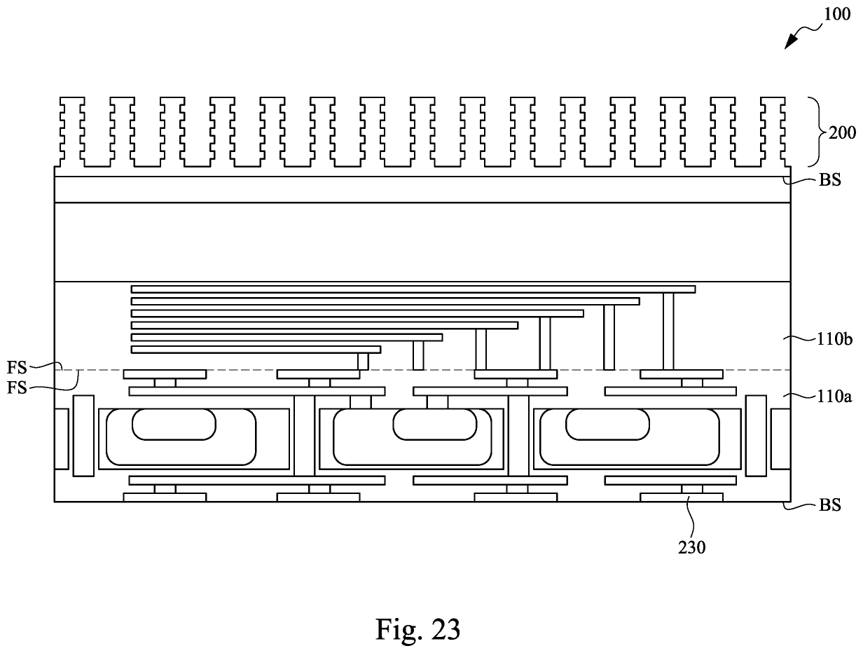

Reference is made to FIG. 22 and FIG. 23. FIG. 22 and FIG. 23 are cross-sectional views of a semiconductor structure, according to different embodiments of the disclosure. The semiconductor structure 100 includes a first semiconductor substrate 110a and a second semiconductor substrate 110b, and the front side FS of the first semiconductor substrate 110a is bonded to the front side FS of the second semiconductor substrate 110b. In some embodiments, the first semiconductor substrate 110a is a CMOS wafer including CMOS components, and the second semiconductor substrate 110b is an array wafer including a staircase connecting structure. Therefore, the semiconductor structure 100 can be referred as a CMOS bonding array (CbA) structure.

As shown in FIG. 22, in some embodiments, the heat dissipating component 200 is disposed on the back side BS of the first semiconductor substrate 110a (e.g. the CMOS wafer), and bonding pads 230 of the semiconductor structure 100 are formed on the back side BS of the second semiconductor substrate 110b (e.g. the array wafer).

As shown in FIG. 23, in some embodiments, the heat dissipating component 200 is disposed on the back side BS of the second semiconductor substrate 110b (e.g. the array wafer), and bonding pads 230 of the semiconductor structure 100 are formed on the back side BS of the first semiconductor substrate 110a (e.g. the CMOS wafer).

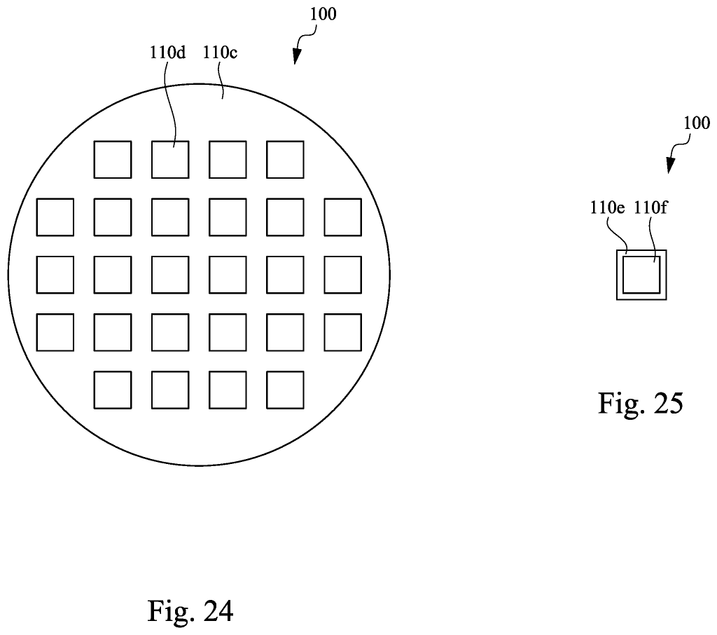

Reference is made to FIG. 24, which is a schematic top view of a semiconductor structure, according to some embodiments of the disclosure. In some embodiments, the semiconductor structure 100 can be a wafer to chip structure which includes a wafer 110c and a plurality of chips 110d bonded on the wafer 110c. The heat dissipating component (not shown) as described above can be disposed on the semiconductor substrate of the wafer 110c or the chips 110d.

Reference is made to FIG. 25, which is a schematic top view of a semiconductor structure, according to some embodiments of the disclosure. In some embodiments, the semiconductor structure 100 can be a chip to chip structure which includes a first chip 110e and a second chip 110f bonded on the first chip 110e. The heat dissipating component (not shown) as described above can be disposed on the semiconductor substrate of the first chip 110e or second chip 110f.

The present disclosure provides a semiconductor structure and a method of forming the same. The semiconductor structure includes the heat dissipating component formed on the semiconductor substrate, in which the heat dissipating component is formed by semiconductor processes and includes protrusions. Each of the protrusions has a wrinkle side surface thereby increasing the surface area of the protrusions, such that the thermal exchange efficiency of the heat dissipating component is improved.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A semiconductor structure comprising:
a semiconductor substrate; and
a heat dissipating component disposed on a surface of the semiconductor substrate, the heat dissipating component comprising a plurality of protrusions, each of the protrusions comprising a plurality of first sections and a plurality of second sections, wherein a dimension of the first sections is different from a dimension of the second sections.

2. The semiconductor structure of claim 1, further comprising:
a liner oxide layer on the surface of the semiconductor substrate; and
a seed layer on the liner oxide layer, wherein bottoms of the protrusions are interconnected by the seed layer.

3. The semiconductor structure of claim 2, wherein a material of the protrusions of the heat dissipating component comprises Ag, Cu, Au, Al, or W.

4. The semiconductor structure of claim 1, wherein the protrusions are directly formed on the surface of the semiconductor substrate, and bottoms of the protrusions are spaced apart from each other.

5. The semiconductor structure of claim 4, wherein bottoms of the protrusions are embedded in the surface of the semiconductor substrate.

6. The semiconductor structure of claim 4, wherein a material of the protrusions of the heat dissipating component comprises graphite sheet, Si, phase change material, liquid metal paste, thermal pad, thermal paste, or AlN.

7. The semiconductor structure of claim 1, wherein the first sections and the second sections are alternately and repetitively arranged.

8. The semiconductor structure of claim 7, wherein each of the protrusions comprises a plurality of third sections, wherein a dimension of the third sections is different from the dimension of the first sections and is different from the dimension of the second sections.

9. The semiconductor structure of claim 1, further comprising a via disposed in the semiconductor substrate, wherein the via is connected to one or more of the protrusions.

10. A semiconductor structure comprising:
a first semiconductor substrate having a front side and a back side;
a second semiconductor substrate having a front side and a back side, wherein the front side of the second semiconductor substrate is bonded to the front side of the first semiconductor substrate; and
a heat dissipating component disposed on the back side of the first semiconductor substrate, the heat dissipating component comprising a plurality of protrusions, each of the protrusions comprising a plurality of first sections and a plurality of second sections, wherein a dimension of the first sections is different from a dimension of the second sections.

11. The semiconductor structure of claim 10, further comprising a plurality of bonding pads disposed on the back side of the second semiconductor substrate.

12. The semiconductor structure of claim 10, wherein the first semiconductor substrate is a CMOS wafer, and the second semiconductor substrate is an array wafer.

13. The semiconductor structure of claim 10, wherein the first semiconductor substrate is an array wafer, and the second semiconductor substrate is a CMOS wafer.

14. A method of forming a semiconductor structure, comprising:
forming a sacrificial stack on a surface of a semiconductor substrate, wherein the sacrificial stack comprises a plurality of first sacrificial layers and a plurality of second sacrificial layers alternately and repetitively arranged, and a material of the first sacrificial layers is different from a material of the second sacrificial layers;
performing an anisotropic etching process to the sacrificial stack to form a plurality of trenches between a plurality of sacrificial structures comprising the first sacrificial layers and the second sacrificial layers;
performing an isotropic etching process to the sacrificial structures to form a plurality of cavities between the first sacrificial layers and the second sacrificial layers;
filling a thermal conductivity material in the trenches and the cavities; and
removing the sacrificial structures, wherein a remaining portion of the thermal conductivity material forms a plurality of protrusions of a heat dissipating component on the surface of a semiconductor substrate.

15. The method of claim 14, further comprising removing a portion of the thermal conductivity material to expose top surfaces of the sacrificial structures, before removing the sacrificial structures.

16. The method of claim 14, wherein the sacrificial stack comprises a plurality of third sacrificial layers, and a material of the third sacrificial layers is different from the material of the first sacrificial layers and is different from the material of the second sacrificial layers.

17. The method of claim 16, wherein a thickness of the third sacrificial layers is different from a thickness of the first sacrificial layers and is different from a thickness of the second sacrificial layers.

18. The method of claim 14, further comprising:
thinning the semiconductor substrate, prior to forming the sacrificial stack on the surface of the semiconductor substrate.

19. The method of claim 14, further comprising:
forming a liner oxide layer on the surface of the semiconductor substrate; and
forming a seed layer on the liner oxide layer, wherein the sacrificial stack is formed on the seed layer.

20. The method of claim 19, wherein filling a thermal conductivity material in the trenches and the cavities comprises performing an electroplating process.
